(19) United States
(12) Patent Application Publication
(10) Pub. No.: US 2012/0013403 A1
(43) Pub. Date: Jan. 19, 2012

(54) AMPLIFIER CIRCUIT

(75) Inventors: Ryusuke SAHARA, Mitaka (JP); Satoshi UENO, Akiruno (JP); Takahiro KAWATA, Higashimurayama (JP)

(73) Assignee: HITACHI, LTD.

(21) Appl. No.: 13/183,101

(22) Filed: Jul. 14, 2011

(30) Foreign Application Priority Data
Jul. 15, 2010 (JP) 2010-160203

(51) Int. Cl. H03F 3/45

(52) U.S. Cl. 330/253

(57) ABSTRACT

An amplifier circuit is configured to be preceded by a single-ended-to-differential translate circuit using a BTL configuration operating at a low voltage and succeeded by amplifiers to amplify output signals VOT and VOB from the single-ended-to-differential translate circuit. The amplifier circuit activates a mute function of the subsequent amplifiers during state transition when the single-ended-to-differential translate circuit turns on. Consequently, the amplifier circuit fixes output signals OUTP and OUTN to 0 V and masks an output noise. The amplifier circuit inactivates the mute function after signals VOT and VOB become stable. Thereby, the amplifier circuit is capable of easily preventing a pop noise using a BTL configuration requested for high voltage output to drive a piezoelectric actuator.

### CLAIM OF PRIORITY

The present application claims priority from Japanese patent application JP 2010-160203 filed on Jul. 15, 2010, the content of which is hereby incorporated by reference into this application.

### FIELD OF THE INVENTION

The present invention relates to a single-ended-to-differential translate circuit using a bridge-tied load (BTL) configuration. More particularly, the invention relates to a technology capable of preventing a pop noise during power-on/off sequence.

### BACKGROUND OF THE INVENTION

In many cases, an audio amplifier circuit uses the BTL configuration that applies audio signals of opposite phases to both terminals of a speaker and approximately doubles the amplitude. The reason is that there is an increasing demand to reduce a power supply voltage and generate high output at a low voltage.

In the related art, an audio system is liable to generate a pop noise that generates unpleasant sound from a speaker or a headphone during power-on/off sequence due to a change in differential output values. The BTL configuration easily generates the pop noise because of the circuit configuration.

In the related art, various methods have been employed to suppress a pop noise on audio amplifiers based on the BTL configuration. To solve the pop noise problem, for example, the method described in Japanese Unexamined Patent Application Publication No. 2009-94635 controls a power-on sequence and connection relation of a speaker amplifier connected to both terminals of a speaker. Consequently, the method causes no potential difference at both terminals of the speaker or prevents an audible frequency range if a potential difference occurs.

As disclosed in Japanese Unexamined Patent Application Publication No. 2009-169612, the touch panel input apparatus allows a piezoelectric actuator to transmit vibration to the finger of a user as an operator so that an operational sense can be haptically fed back. The piezoelectric actuator or the touch panel provided with the piezoelectric actuator generates sound.

### SUMMARY OF THE INVENTION

The audio amplifier disclosed in Japanese Unexamined Patent Application Publication No. 2009-94635 allows the single-ended-to-differential translate circuit using the BTL configuration to generate intended amplitude. No additional amplifier is needed independently of the single-ended-to-differential translate circuit. The single-ended-to-differential translate circuit prevents a pop noise waveform. However, an output from the single-ended-to-differential translate circuit is directly applied to the speaker. For example, a noise generated in switching control might affect the output. In principle, it is difficult for the single-ended-to-differential translate circuit using the BTL configuration to maintain the same electric potential. Accordingly, a potential difference might be caused in differential outputs from the single-ended-to-differential translate circuit to generate a pop noise. The control method and the circuit configuration are complicated in order to prevent a potential difference in differential outputs from the single-ended-to-differential translate circuit.

The piezoelectric actuator disclosed in Japanese Unexamined Patent Application Publication No. 2009-169612 requires ranges of drive voltages depending on uses. The piezoelectric actuator requires high voltage amplitude ranging from 40 to 200 voltages or higher when a touch panel is driven to generate large haptic sense and sound volume as intended for the invention or when a low-cost single-layer piezoelectric actuator is used, for example.

An amplifier might be provided in addition to the single-ended-to-differential translate circuit using the BTL configuration in order to generate high output voltage. However, the amplifier amplifies a noise generated from the single-ended-to-differential translate circuit and generates a pop noise. As a result, the touch panel generates unpleasant sound or is unnecessarily vibrated even though the vibration is unneeded.

The present invention has been made in consideration of the foregoing. It is therefore an object of the invention to provide an amplifier circuit capable of easily preventing a pop noise using a BTL configuration requested for high voltage output to drive a piezoelectric actuator, for example.

In the related art, a single-ended-to-differential translate circuit prevents a pop noise. By contrast, the invention allows a noise occurrence on a single-ended-to-differential translate circuit and controls timing to mute output from an amplifier circuit provided subsequently to the single-ended-to-differential translate circuit so that no noise is output from the amplifier circuit.

The following summarizes the representative aspects of the invention disclosed in this application.

An amplifier circuit includes a single-ended-to-differential translate circuit using a BTL configuration; and an amplifier that amplifies a differential output signal from the single-ended-to-differential translate circuit. A power-on control signal is input to the single-ended-to-differential translate circuit. The amplifier is supplied with a mute control signal that masks an output noise in the differential output signal when the single-ended-to-differential translate circuit turns on and off based on the power-on control signal.

A single-ended-to-differential translate circuit turns on in accordance with a first control signal being input at a first level thereof at a first timing, to output a differential output signal, and turns off in accordance with the first control signal being input at a second level thereof at a fourth timing after the first timing. An amplifier amplifies the differential output signal and generates an output signal in accordance with a second control signal being input at a first level thereof at a second timing between the first timing and the fourth timing, and mutes the output signal in accordance with the second control signal being input at a second level thereof at a third timing between the second timing and the fourth timing. An interval between the first timing and the second timing is longer than a time period to stabilize the differential output signal from the first timing. An interval between the third timing and the fourth timing is longer than a time period to stabilize the output signal from the third timing.

According to an aspect of the invention, an amplifier circuit can prevent a pop noise based on a simple configuration.

### BRIEF DESCRIPTION OF THE DRAWINGS

FIG. 1 is a circuit diagram showing a configuration example of an amplifier circuit according to a first embodiment;

FIG. 2 is a circuit diagram showing a configuration example of a single-ended-to-differential translate circuit according to the first embodiment;

FIG. 3 is a circuit diagram showing a configuration example of a high-voltage amplifier according to the first embodiment;

FIG. 4 exemplifies a timing chart of signals during a power-on/off sequence according to the first embodiment;

FIG. 5 is a circuit diagram showing a configuration example of an amplifier circuit according to a second embodiment;

FIG. 6 is a circuit diagram showing a configuration example of a control circuit according to the second embodiment;

FIG. 7 exemplifies a signal input pattern according to the second embodiment; and

FIG. 8 exemplifies a timing chart of signals according to the second embodiment.

### DETAILED DESCRIPTION OF THE PREFERRED EMBODIMENTS

### First Embodiment

The following describes the first embodiment of the invention with reference to the accompanying drawings.

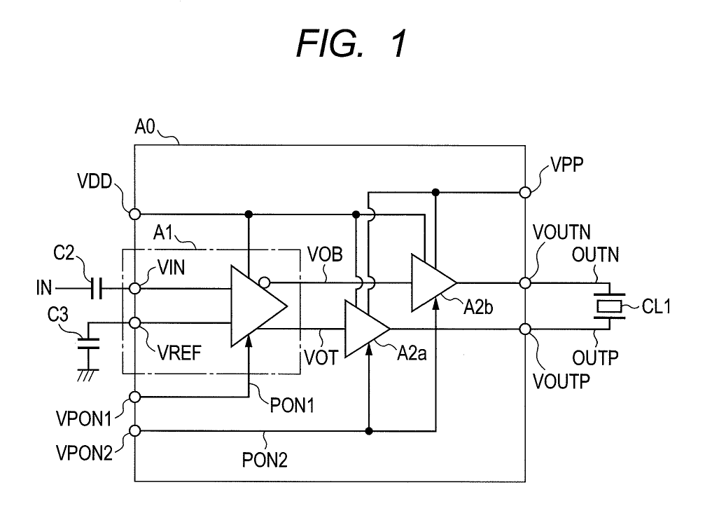

FIG. 1 is a circuit diagram showing a configuration example of an amplifier circuit according to the first embodiment. As shown in FIG. 1, an amplifier circuit A0 according to the embodiment includes a single-ended-to-differential translate circuit A1, amplifiers A2a and A2b, a capacitor C2, and a stabilizing capacitor C3. The single-ended-to-differential translate circuit A1 converts single input into differential output. The amplifiers A2a and A2b amplify differential outputs VOT and VOB from the single-ended-to-differential translate circuit A1 into high voltages. The capacitor C2 forms a high pass filter. The stabilizing capacitor C3 is connected to a reference voltage terminal VREF. A piezoelectric actuator CL1 is connected to output terminals VOUTP and VOUTN of the amplifiers A2a and A2b and is supplied with output signals OUTP and OUTN from the amplifiers A2a and A2b. A high voltage of 40 V to 200 V is supplied to a high voltage power supply terminal VPP. A low voltage of 3 V to 5.5 V is supplied to a low voltage power supply terminal VDD.

The high voltage power supply terminal VPP might be directly supplied with a high voltage from an external power supply unit or with a voltage generated by a boosting DC-DC converter contained in an LSI mounted with the amplifier circuit. However, mounting an external power supply unit is difficult when the amplifier circuit is used for mobile devices. In such a case, the boosting DC-DC converter provides an effective method.

The first embodiment needs to drive the piezoelectric actuator CL1 that requires high voltage output. Accordingly, an output section needs an output circuit using a high-voltage device. For this purpose, the single-ended-to-differential translate circuit using the BTL configuration operates at a low voltage. The high-voltage amplifier using the high-voltage device is subsequently provided to amplify an output signal to a high voltage. The advantage of this configuration will be readily ascertained by referring to the following description of operations according to the first embodiment.

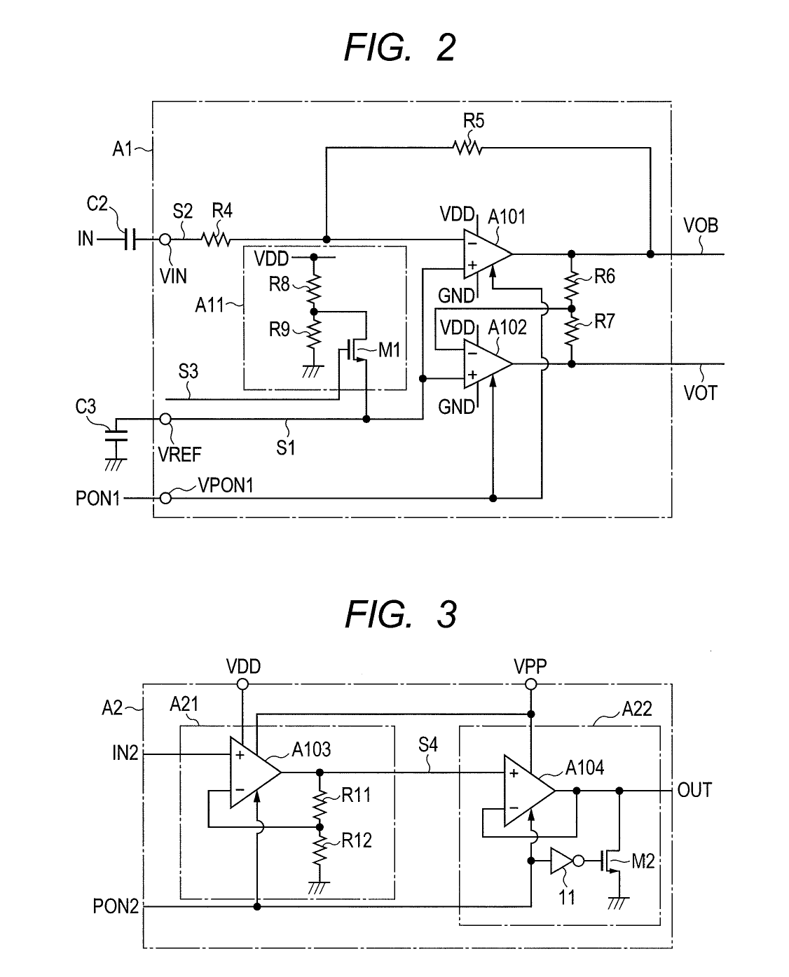

The configuration of the single-ended-to-differential translate circuit A1 in FIG. 1 will be described with reference to FIG. 2. A haptic sense or audio input signal IN is input to the single-ended-to-differential translate circuit A1 through a high pass filter including the capacitor C2 and a resistor R4. The high pass filter removes direct current components or a low frequency noise from the input signal.

A signal S1 is supplied with the reference voltage. To do this, the reference voltage is supplied to the terminal VREF from the outside. Alternatively, a reference voltage generation circuit A11 generates a voltage through a transistor M1. For example, the transistor M1 can be MOSFET (Metal-Oxide Semiconductor Field Effect Transistor).

A signal S3 turns off the transistor M1 to use the former technique of supplying the reference voltage from the outside. Alternatively, the signal S3 turns on the transistor M1 to use the latter technique. The reference voltage generation circuit A11 according to the embodiment generates the reference voltage by dividing a power supply voltage VDD using resistors R8 and R9. The technique of generating the reference voltage is not limited to this circuit scheme but can use various methods. The capacitor C3 stabilizes the signal S1. The capacitor C3 forms a low pass filter in combination with the resistors R8 and R9 or with a resistor externally connected to the terminal VREF and reduces a noise in the signal S1.

A low voltage amplifier A101 and resistors R4 and R5 form an inverting amplifier circuit. The inverting amplifier circuit inverts a signal S2 input to a terminal VIN through the capacitor C2 into an inverted signal of the input signal S2 and outputs the inverted signal to a signal VOB. The signal VOB is further inverted by an inverting amplifier circuit formed by a low voltage amplifier A102 and resistors R6 and R7 and is output as a normal signal of the input signal S2 to a signal VOT. The resistors R6 and R7 are configured to the same resistance value because the signals VOT and VOB need to have the same amplitude.

As a result, the haptic sense or audio input signal IN as single input is converted into a differential signal between the normal signal VOT and the inverted signal VOB.

A signal PON1 input to a terminal VPON1 functions as a power-on signal for the low voltage amplifiers A101 and A102. The signal PON1, when set to the low level, turns off the low voltage amplifiers A101 and A102. The signal PON1, when set to the high level, turns on the low voltage amplifiers A101 and A102.

A ratio of resistors R5 to R4, that is R5/R4, determines a gain of the single-ended-to-differential translate circuit A1. Generally, the gain is multiplied by one to several times because the power supply voltage VDD is low.

The following describes the configuration of a high-voltage amplifier A2 (A2a and A2b) in FIG. 1 with reference to FIG. 3. The high-voltage amplifier A2 receives a low voltage input signal output from the single-ended-to-differential translate circuit A1 and amplifies the input signal to high voltage output. A low voltage input signal IN2 is supplied to a gain amplifier A21 and is amplified to a high voltage amplitude. The gain amplifier A21 includes a high voltage amplifier A103 and resistors R11 and R12, and functions as a non-inverting amplifier circuit. The input signal IN2 is multiplied by (R11+R12)/R12 and is output as a signal S4. A voltage follower amplifier A22 includes a high voltage amplifier A104, a transistor M2, and an inverter I1, and increases a driving force of the piezoelectric actuator CL1. The voltage follower amplifier A22 converts the impedance of the signal S4 and outputs it as a signal OUT.

The high voltage amplifier A103 is connected to the low voltage power supply VDD and the high voltage power supply VPP in order to amplify a low voltage to a high voltage. The high voltage amplifier A104 is connected to only the high voltage power supply VPP because high voltages are input and output.

A signal PON2 input to a terminal VPON2 functions as a power-on signal for the high voltage amplifiers A103 and A104. The signal PON2, when set to the low level, turns off the low voltage amplifiers A103 and A104. The signal PON2, when set to the high level, turns on the low voltage amplifiers A103 and A104. A transistor M2 is connected between an output signal OUT and GND in the voltage follower amplifier A22. The gate of the transistor M2 is supplied with a signal PON2 inverted by the inverter I1. The signal PON2, when set to the low level, enables the transistor M2 as on-resistance for connection between the signal OUT and GND. The signal PON2, when set to the high level, causes high impedance between the signal OUT and GND. The signal PON2, when set to the low level, is discharged to GND. The signal PON2, when set to the high level, generates the output signals OUTP and OUTN.

As described above, the signal PON2 according to the first embodiment provides two functions at the same time. One is to control whether the high-voltage amplifiers A2a and A2b mute an output signal. The other is to control whether the high-voltage amplifiers A2a and A2b are turned off.

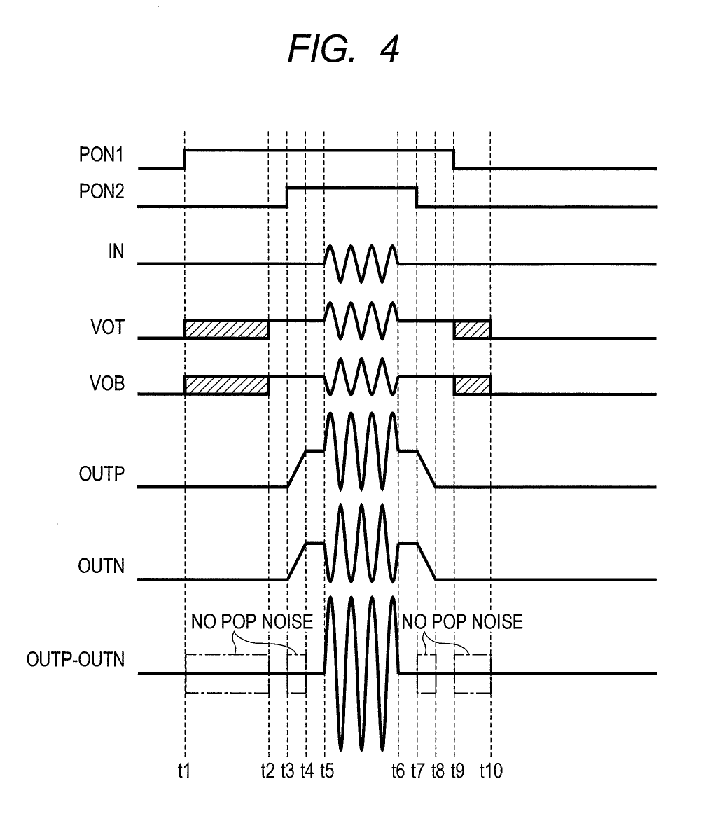

The following describes operations and signal states during a power-on/off sequence on the amplifier circuit in FIG. 1 with reference to a timing chart in FIG. 4. It is assumed that the low voltage power supply VDD and the high voltage power supply VPP are always applied. It is also assumed that the power-on/off sequence applies to the power supply, the low or high voltage amplifier, and the other circuits.

The following describes operations when the power is turned on. The signal PON1 goes to the high level at time t1. The low voltage amplifiers A101 and A102 are turned on to start operating the single-ended-to-differential translate circuit A1. The signals VOT and VOB output from the single-ended-to-differential translate circuit go through different transition states, reach the same voltage as the reference voltage supplied to the signal S1, and become stable by time t2.

A time period from the time t1 to the time t2 depends on cutoff frequencies of the high pass filter formed by the capacitor C2 and the low pass filter formed by the capacitor C3. Normally, a pop noise at startup decreases, as a cutoff frequency of the low pass filter is sufficiently low in comparison with a cutoff frequency of the high pass filter. However, this is impractical because a long power-on startup time is needed to ensure a stable state.

In this case, a pop noise occurs as a differential output between VOT and VOB during the period between the time t1 and the time t2. To solve this problem, the first embodiment inputs a mute signal during the period between the time t1 and the time t2 in order to mask the pop noise. In other words, the subsequent high-voltage amplifier A2 is supplied with the signal PON2 set to the low level, i.e., the signal OUTP or OUTN is not output. Accordingly, both terminals of the piezoelectric actuator CL1 remain supplied with 0 V as a differential signal output OUTP-OUTN. The piezoelectric actuator CL1 causes no pop noise.

The signal PON2 goes to the high level at time t3 after the time t2 when the voltages are stabilized for the signals VOT and VOB output from the single-ended-to-differential translate circuit. At the time t3, the high voltage amplifiers A103 and A104 turn on. At the same time, the transistor M2 in FIG. 3 turns off to simultaneously raise the signals OUTP and OUTN.

The high-voltage amplifiers A2a and A2b are equivalent to the high-voltage amplifier A2 in FIG. 3 and are provided as circuits having the same configuration. The signals VOT and VOB use the same voltage. The signals OUTP and OUTN simultaneously rise at the same through-rate and are stabilized to the same voltage at time t4.

The differential signal output OUTP-OUTN remains 0 V from the time t3 to t4. No pop noise occurs.

A haptic sense or audio input signal IN is supplied at the amplitude of V1pp (pp: Peak-to-Peak) from the time t5 to t6, for example. It is possible to ensure the amplitude of OUTP-OUTN=V1pp×(R5/R4)×((R11+R12)/R12)×2 as a total of the amplitude of the single-ended-to-differential translate circuit, the amplitude of the high-voltage amplifier, and the amplitude of the BTL configuration as described above.

The single-ended-to-differential translate circuit A1 and the high-voltage amplifier A2 correspond to amplification gain values of R5/R4=1 and (R11+R12)/R12=50, respectively. In this case, it is possible to ensure the gain of OUTP-OUTN=V1pp×1×50×2=V1pp×100.

There may be a case where the signals VOT and VOB output from the preceding single-ended-to-differential translate circuit go through the transition state. Under this condition, the method according to the first embodiment can prevent a pop noise when the timing is controlled so as to turn off the signal PON2 to be input to the subsequent high-voltage amplifiers A2a and A2b and fix the output to 0 V. In this case, a pop noise, if any, is masked in the output from the preceding single-ended-to-differential translate circuit. For example, the startup time can be shortened by increasing a cutoff frequency of the low pass filter formed by the capacitor C3 in comparison with a cutoff frequency of the high pass filter formed by the capacitor C2.

The following describes operations when the power is turned off. At the time t6, the haptic sense or audio input signal IN stops being input. The output signals OUTP and OUTN are stabilized to the same output voltage. At time t7, the signal PON2 goes to the low level. The transistor M2 in FIG. 3 turns on to simultaneously lower the output signals OUTP and OUTN. From the time t7 to t8, the signals OUTP and OUTN simultaneously fall to 0 V at the same through-rate because the high-voltage amplifiers A2a and A2b are the same circuit. The differential signal OUTP-OUN remains 0 V. No pop noise occurs.

The signal PON1 goes to the low level at time t9 after the time t8 when the output signals OUTP and OUTN are lowered to 0 V to become stable. The low voltage amplifiers A101 and A102 turn off to stop the single-ended-to-differential translate circuit A1. Similarly to the power-on sequence, the signals VOT and VOB output from the single-ended-to-differential translate circuit go through different transition states and are set to 0 V by time t10 to become stable.

A pop noise occurs as a differential output VOT-VOB during the period from time t9 to t10. During this period, the first embodiment supplies a mute signal to mask the pop noise. In other words, the signal PON2 input to the subsequent high-voltage amplifier A2 is controlled to the low level, the state in which the signals OUTP and OUTN are not output. Consequently, both terminals of the piezoelectric actuator CL1 remain supplied with the differential signal output OUTP-OUTN set to 0 V. No pop noise occurs on the piezoelectric actuator CL1.

As described above, the amplifier circuit A0 mutes outputs from the subsequent high-voltage amplifiers A2a and A2b in the power-on/off sequence that might cause a pop noise on the single-ended-to-differential translate circuit A1. Accordingly, no pop noise occurs on the piezoelectric actuator CL1. As a result, the simple timing control over the signals PON1 and PON2 can prevent a pop noise.

The signals PON1 and PON2 each control the power-on sequence. Turning the power off can conserve the power consumption while the piezoelectric actuator need not be driven. According to the first embodiment, the signal PON2 functions as not only a power-on control signal but also a mute control signal. The timing control over the power-on control signal can simultaneously conserve the power consumption and decrease a pop noise.

The subsequent high-voltage amplifiers A2a and A2b need to decrease differences among the offset, through-rate, and gain in order to suppress noise while disabling and enabling the mute condition of the high-voltage amplifiers. For this purpose, both high-voltage amplifiers use the same circuit configuration. In addition, the circuit layout can be well designed to improve the symmetric property between the OUTP and OUTN sides such as equal signal line lengths and symmetric placement of devices so that a pop noise can be prevented to be free of adverse effects on the practical use.

### Second Embodiment

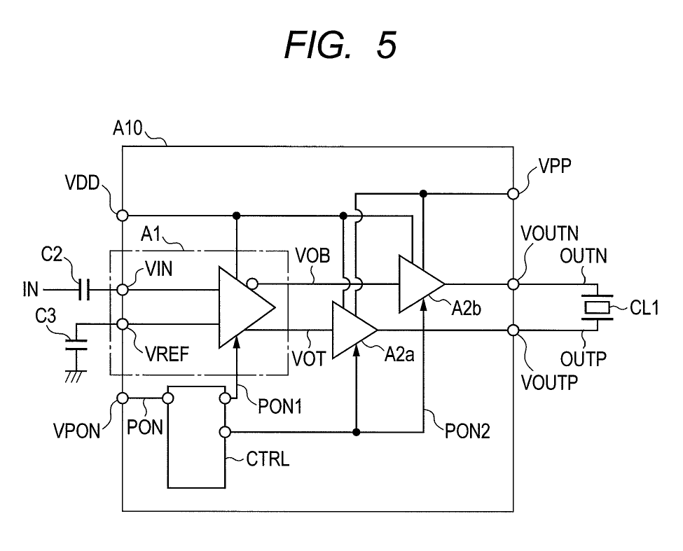

FIG. 5 is a circuit diagram showing a configuration of an amplifier circuit A10 according to the second embodiment with modifications to the power-on signal control method according to the first embodiment of the invention.

The second embodiment features a control circuit CTRL. The control circuit CTRL allows a logic circuit using a delay device to generate the signal PON1 supplied to the single-ended-to-differential translate circuit and the signal PON2 supplied to the amplifier circuit from a control signal generation signal PON at a given timing.

The control circuit CTRL is also capable of adjusting rise/fall timings of the signals PON1 and PON2. For example, the control circuit CTRL is mounted with a register circuit that can provide variable timings corresponding to the times t1, t3, t7, and t9 (see FIG. 4) for turning on or off the control signals PON1 and PON2 output from the control circuit CTRL in accordance with the startup time to be determined later based on the device configuration. In terms of uses, configurations common to the amplifier circuit A0 according to the first embodiment are depicted by the same reference numerals and a description is omitted for simplicity.

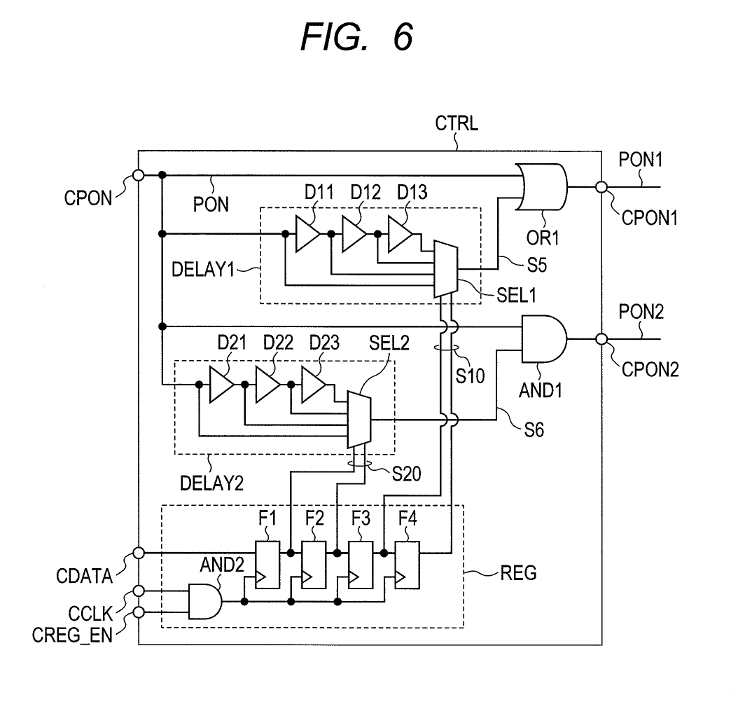

FIG. 6 is a circuit diagram illustrating the control circuit CTRL used for the second embodiment. The control circuit CTRL includes delay circuits DELAY1 and DELAY2, a register circuit REG, an OR circuit OR1, and an AND circuit AND1. A terminal. CPON is connected to the terminal VPON in FIG. 5 and is supplied with an input signal PON. Terminals CPON1 and CPON2 output signals PON1 and PON2, respectively. Terminals CDATA, CCLK, and CREG_EN function as signal input terminals used to set the register circuit REG.

The delay circuit' DELAY1 includes delay devices D11 through D13 and a selector circuit SEL1. The delay circuit DELAY2 includes delay devices D21 through D23 and a selector circuit SEL2. The delay circuits DELAY1 and DELAY2 each delay an input signal for the variable delay time and output a corresponding signal. For example, the delay circuit DELAY1 inputs the signal PON and output signals from the delay devices D11, D12, and D13 to the selector circuit SEL1. A select signal S10 selects one of the SEL1 input signals and outputs the selected signal as a signal S5. The delay circuit DELAY2 is configured similarly to DELAY1.

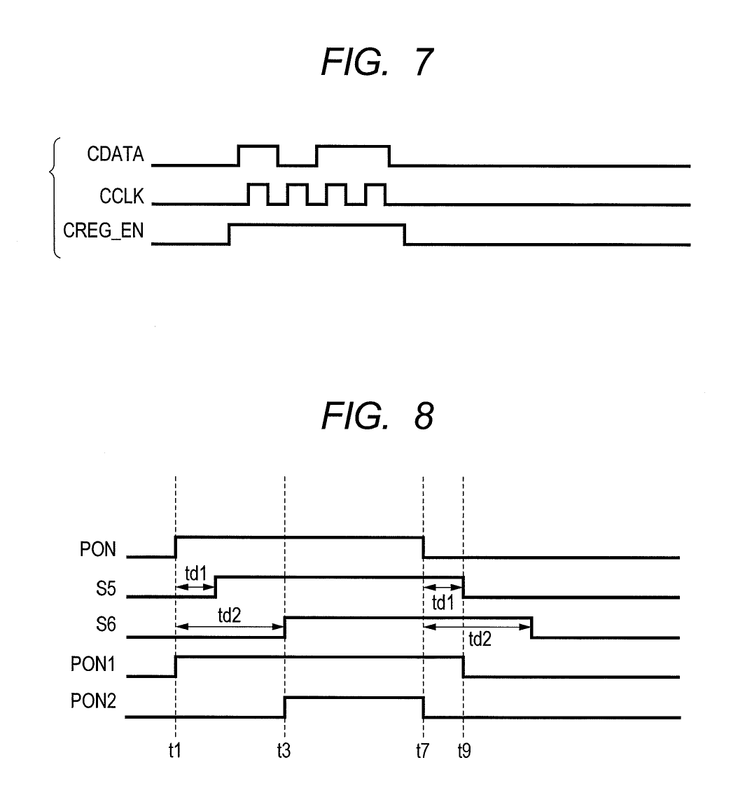

The register circuit REG includes flip-flop circuits F1 through F4 and an AND circuit AND2. Input terminals CDATA, CCLK, and CREG_EN are used for writing to the register. Delay time setting data is input to CDATA. A write clock is input to CCLK. A write enable signal is input to CREG_EN. For example, a signal input pattern as shown in FIG. 7 supplies logical values to the flip-flops F1 through F4. This operation determines values of the select signals S10 and S20 that determine delay times for the delay circuits DELAY1 and DELAY2, respectively.

Obviously, the number of delay device stages and the number of register stages according to the embodiment are examples and vary with uses.

Operations of the control circuit CTRL will be described with reference to FIG. 8. To simplify the description, it is assumed that the circuits OR1, AND1, SEL1, and SEL2 cause no device delay time.

The signal PON goes to the high level at the time t1. The output signal PON1 from the OR circuit OR1 then goes to the high level regardless of the signal S5. A signal S6 input to the AND circuit AND1 remains the low level. Accordingly, the output signal PON2 remains the low level. The signal S6 goes to the high level at the time t3 after delay time td2 generated by the delay circuit DELAY2. The output signal PON2 from the AND circuit AND1 then goes to the high level. The delay time td2 is configured to be longer than the transition time for the signals VOT and VOB in FIG. 4 to rise.

The signal PON goes to the low level at the time t7. The output signal PON2 from the AND circuit AND1 then goes to the low level. The input signal S5 remains the high level. Accordingly, the output signal PON1 from the OR circuit OR1 remains the high level. The signal S5 goes to the low level at the time t9 after delay time td1 generated by the delay circuit DELAY1. The output signal PON1 from the OR circuit OR1 then goes to the low level. The delay time td1 is configured to be longer than the time for the signals OUTP and OUTN in FIG. 4 to fall.

The signal S6 goes to the low level after the delay time td2 from the time t7 but is independent of the PON signal.

The control circuit using the delay circuits can generate the signals PON1 and PON2 at a given timing only using an input of the power-on/off signal PON without direct control over the timing using an external signal. In addition, the register circuit is also provided to generate the signals PON1 and PON2 at proper timings. As a result, the amplifier circuit A10 can be turned on or off without a pop noise.

While there have been described the embodiments of the present invention, it is to be distinctly understood by those skilled in the art that the present invention is not limited thereto but may be otherwise variously embodied within the spirit and scope of the invention and may be applicable to an appropriate combination of the embodiments.

What is claimed is:

1. An amplifier circuit comprising:
a single-ended-to-differential translate circuit using a BTL configuration; and
an amplifier that amplifies a differential output signal from the single-ended-to-differential translate circuit,
wherein a power-on control signal is input to the single-ended-to-differential translate circuit; and
wherein the amplifier is supplied with a mute control signal that masks an output noise in the differential output signal when the single-ended-to-differential translate circuit turns on and off based on the power-on control signal.

2. The amplifier circuit according to claim 1,
wherein the mute control signal is equivalent to the power-on control signal for the amplifier.

3. The amplifier circuit according to claim 1, further comprising:
a control circuit that provides timing control to generate the mute control signal and the power-on control signal based on a control signal that controls generation of the mute control signal and the power-on control signal.

4. The amplifier circuit according to claim 3, further comprising:
a register circuit that makes variable a timing to input the power-on control signal to the single-ended-to-differential translate circuit and makes variable a timing to input the mute control signal to the amplifier.

5. The amplifier circuit according to claim 1,
wherein a power supply voltage used for an output section of the amplifier is higher than a power supply voltage used for the single-ended-to-differential translate circuit.

6. An amplifier circuit comprising:
a single-ended-to-differential translate circuit that turns on in accordance with a first control signal being input at a first level thereof at a first timing, to output a differential output signal, and turns off in accordance with the first control signal being input at a second level thereof at a fourth timing after the first timing; and
an amplifier that amplifies the differential output signal and generates an output signal in accordance with a second control signal being input at a first level thereof at a second timing between the first timing and the fourth timing, and mutes the output signal in accordance with the second control signal being input at a second level thereof at a third timing between the second timing and the fourth timing,
wherein an interval between the first timing and the second timing is longer than a time period to stabilize the differential output signal from the first timing; and
wherein an interval between the third timing and the fourth timing is longer than a time period to stabilize the output signal from the third timing.

7. The amplifier circuit according to claim 6,
wherein the second control signal is equivalent to a mute control signal that masks an output noise in the differential output signal during state transition when the single-ended-to-differential translate circuit turns on and off.

8. The amplifier circuit according to claim 6,
wherein the second control signal controls a power-on/off sequence of the amplifier.

9. The amplifier circuit according to claim 6, further comprising:
a control circuit that generates the first control signal being input at the first timing and the second timing and the second control signal being input at the third timing and the fourth timing based on a control signal that controls generation of the first control signal and the second control signal.

10. The amplifier circuit according to claim 6, further comprising:
a register circuit that makes variable the first timing, the second timing, the third timing, and the fourth timing.

11. The amplifier circuit according to claim 6,
wherein a power supply voltage used for an output section of the amplifier is higher than a power supply voltage used for the single-ended-to-differential translate circuit.
